(19) United States
(12) Patent Application Publication
(10) Pub. No.: US 2025/0329635 A1
(43) Pub. Date: Oct. 23, 2025

(54) SEMICONDUCTOR DIE COUPLING WITH INDUCTIVE COILS

(71) Applicant: Micron Technology, Inc., Boise, ID (US)

(72) Inventor: Timothy M. Hollis, Meridian, ID (US)

(21) Appl. No.: 19/087,231

(22) Filed: Mar. 21, 2025

Related U.S. Application Data
(60) Provisional application No. 63/635,521, filed on Apr. 17, 2024.

(51) Int. Cl. H01L 23/522; H01L 23/00; H01L 25/04

(52) U.S. Cl. CPC H01L 23/5227; H01L 24/05; H01L 24/16; H01L 25/04; H01L 2224/0233; H01L 2224/02375; H01L 2224/16145; H01L 2225/06513; H01L 2225/06531

(57) ABSTRACT

Systems and devices for semiconductor die coupling with inductive coils are described. A semiconductor device may include one or more inductive coils to enhance signal quality of signals communicated over conductive lines and to support improved processing bandwidth. The semiconductor device may include multiple dies and each die may include respective circuitry. The respective circuitry may be coupled with the one or more inductive coils. In some cases, each die of the semiconductor device may respectively include one or more inductive coils that couple die circuitry with a same channel. In some cases, a redistribution layer that is shared by each die may be configured with one or more inductive coils that are coupled with each die. Each die may be coupled with the one or more inductive coils based on a conductive pillar or based on a hybrid bond.

### CROSS REFERENCE

The present Application for Patent claims priority to U.S. Patent Application No. 63/635,521 by Hollis, entitled “SEMICONDUCTOR DIE COUPLING WITH INDUCTIVE COILS,” filed Apr. 17, 2024, which is assigned to the assignee hereof, and which is expressly incorporated by reference in its entirety herein.

### TECHNICAL FIELD

The following relates to one or more systems for memory, including semiconductor die coupling with inductive coils.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

Some memory devices may include multiple dies that are coupled with a same point on a channel. Such shared couplings may be associated with increased parasitic impedance and increased load impedance.

### BRIEF DESCRIPTION OF THE DRAWINGS

FIG. 1 shows an example of a system that supports semiconductor die coupling with inductive coils in accordance with examples as disclosed herein.

FIG. 2A shows an example of a semiconductor device that supports semiconductor die coupling with inductive coils in accordance with examples as disclosed herein.

FIG. 2B shows an example of an inductive coil that supports semiconductor die coupling with inductive coils in accordance with examples as disclosed herein.

FIGS. 3 through 5 show examples of semiconductor devices that support semiconductor die coupling with inductive coils in accordance with examples as disclosed herein.

### DETAILED DESCRIPTION

In some semiconductor devices (e.g., memory systems), internal circuitry and other internal components (e.g., memory arrays, memory cells, conductor traces) may be reduced in size to increase device density, improve device performance, and improve manufacturing efficiency, among other benefits. However, reducing the internal circuitry of semiconductor devices may also degrade electrical signal quality and reduce processing bandwidth capability (e.g., processing speed). Thus, techniques may be utilized to preserve and enhance signal quality and to support relatively high bandwidth capabilities. For instance, multiple dies (e.g., a top die and a bottom die) of a semiconductor device (e.g., a dual-die package) may be packaged together (e.g., formed, coupled, bonded) in a face-to-face technique (e.g., front side-to-front side). In face-to-face packaging, respective die front sides may face each other and may be coupled with a same channel (e.g., an input/output (I/O) channel, a redistribution layer (RDL)). Such face-to-face packaging may reduce (e.g., minimize) a physical distance between the die circuitry (e.g., memory array circuitry) and the shared channel for each die of the semiconductor device. However, such techniques may be associated with suboptimal effects such as parasitic resistance and capacitance (e.g., associated with edge-to-center RDL traces), which may reduce signal integrity and bandwidth capabilities. Further, because multiple dies may share a same coupling point (e.g., the same channel, a same contact at the RDL) a load impedance (e.g., load capacitance) may increase, which may further reduce signal integrity, thus constraining semiconductor device (e.g., memory array) densification and performance speeds.

In accordance with one or more techniques described herein, a semiconductor device (e.g., a face-to-face dual-die package, a memory system) may include one or more inductive coils (e.g., one or more T-coils, a mutually inductive coil component, one or more spiral-shaped coils) to enhance signal quality and to support improved processing bandwidth (e.g., in face-to-face packaging). The semiconductor device may include multiple dies (e.g., a top die and a bottom die of a dual-die package), and each die may include respective circuitry (e.g., transmission circuitry, reception circuitry, memory array circuitry, electrostatic discharge (ESD) circuitry, or other circuitry) that is coupled with the one or more inductive coils. In some examples, each die of the semiconductor device may respectively include one or more inductive coils (e.g., each die may include respective T-coils) that couple die circuitry with a shared channel (e.g., an RDL, a same I/O channel). In some other examples, an RDL that is shared by each die may be configured with one or more inductive coils that are commonly coupled with the dies (e.g., a T-coil may be included in the RDL between a top die and a bottom die and may be coupled with both dies). Each die may be coupled with the one or more inductive coils based on a conductive pillar (e.g., a solder contact, a copper pillar) or based on a hybrid bonding technique. Thus, the one or more inductive coils may counteract adverse effects in the semiconductor device such as increased parasitic capacitance and increased load capacitance associated with couplings shared by different dies (e.g., by matching or equalizing an impedance induced by the parasitic and load capacitance). Accordingly, semiconductor devices may be enabled to support improved signal integrity and improved bandwidth capability (e.g., faster processing speeds), which may further enable improved densification of semiconductor components.

In addition to applicability in memory systems as described herein, techniques for semiconductor die coupling with inductive coils may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling faster processing speeds and memory access speeds, which may decrease processing or latency times, improve response times, or otherwise improve user experience, among other benefits.

Features of the disclosure are illustrated and described in the context of systems. Features of the disclosure are further illustrated and described in the context of semiconductor devices and inductive coils.

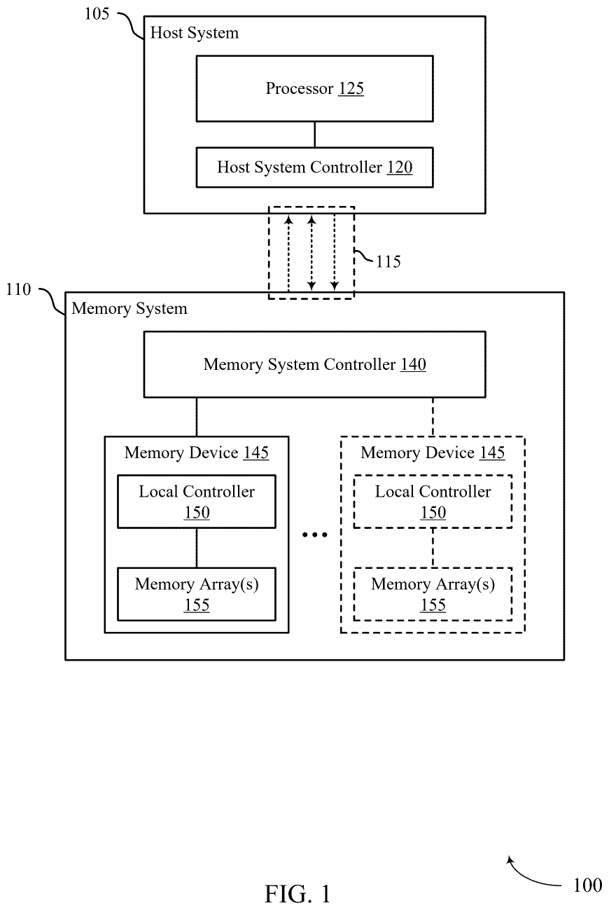

FIG. 1 illustrates an example of a system 100 that supports semiconductor die coupling with inductive coils in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

In accordance with one or more techniques described herein, a system 100 (e.g., a face-to-face dual-die package, a memory system 110) may include one or more inductive coils (e.g., one or more T-coils, a mutually inductive coil component) to enhance signal quality and to support improved processing bandwidth (e.g., in face-to-face packaging). For example, the memory system 110 may include multiple dies (e.g., a top die and a bottom die of a dual-die package, multiple memory devices 145), and each die may include respective circuitry (e.g., transmission circuitry, receive circuitry, memory arrays 155, and other circuitry) that is coupled with the one or more inductive coils. In some examples, each die of the memory system 110 may respectively include one or more inductive coils that couple die circuitry with a shared channel (e.g., an RDL, a same I/O channel). In some other examples, an RDL that is shared by each die may be configured with one or more inductive coils that are commonly coupled with the respective die circuitry. Each die may be coupled with the one or more inductive coils based on a conductive pillar or based on a hybrid bonding technique. By including the one or more inductive coils the system 100 may be enabled to support improved signal integrity and faster processing speeds, which may further enable improved densification of the system 100.

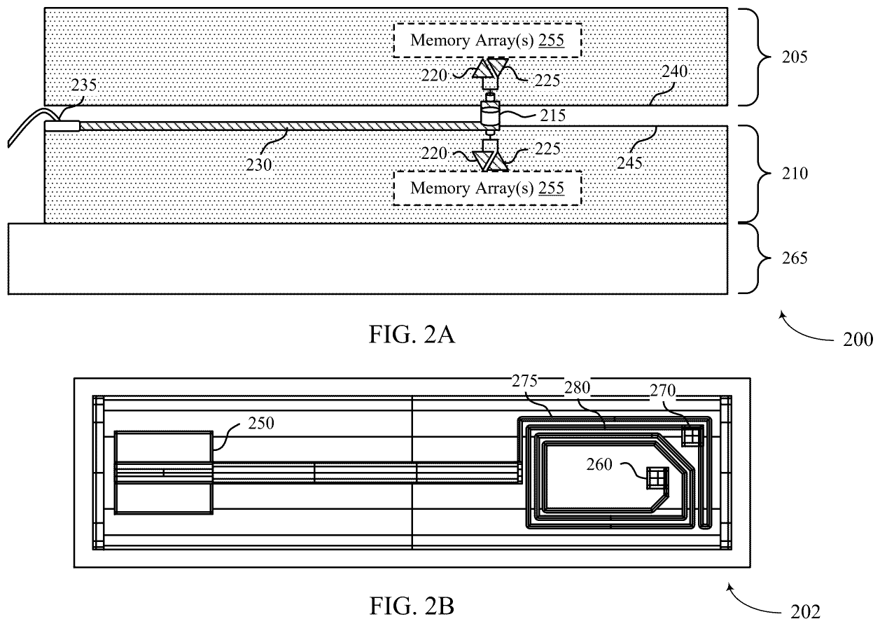

FIG. 2A shows an example of a semiconductor device 200 that supports semiconductor die coupling with inductive coils in accordance with examples as disclosed herein. The semiconductor device 200 may be an example of or include a system 100, a host system 105, a memory system 110, or other device a described herein, including with reference to FIG. 1. The semiconductor device 200 may include a die 205 (e.g., a top die, a memory array die, a memory device 145, a semiconductor die), a die 210 (e.g., a bottom die, a memory array die, a memory device 145, a semiconductor die), and a substrate 265 (e.g., a package substrate, positioned below the die 205 and the die 210).

The semiconductor device 200 may be an example of a face-to-face dual-die package, where a front side 240 (e.g., a face) of the die 205 (e.g., the top die) may be coupled with a front side 245 (e.g., a face) of the die 210 (e.g., the bottom die) via a channel 215 (e.g., a contact, a solder ball, a copper pillar, a physical channel). In such a packaging configuration, pin placement for each die may be a mirror image of each other so that when the front sides are placed together common pins on each die connect. A “front side” may refer to a side of a die that is opposite a substrate on which the die was originally manufactured and may include a one or more interfaces (e.g., bonding pads, solder pads, probe pads) for making electrical connections with other dies or other components. The semiconductor device 200 may also include and RDL 230 (e.g., a conductive metal layer, an aluminum layer), which may include various conductive lines (e.g., traces) that support signaling, power delivery, control, and other operations associated with the die 205 and the die 210. Each die may respectively include circuitry (e.g., electronic circuit elements, logic circuitry) such as transmission circuitry 220 (e.g., driver circuitry), reception circuitry 225 (e.g., receive circuitry, may also include ESD circuitry), and memory arrays 255 (e.g., memory cell circuitry, memory array circuitry). The respective memory arrays 255 may be coupled with the channel 215 and the RDL 230) via the transmission circuitry 220 and the reception circuitry 225 (e.g., and a corresponding DQ pad at the die face). In some cases, there may be a separation (e.g., a gap) between the die 205 and the die 210 to allow space for a wire bond 235 (e.g., including a bond wire and a contact), which may be coupled with RDL 230.

In some cases, the various components within the semiconductor device 200 (e.g., within the die 205, within the die 210, the RDL 230) may be reduced in size to reduce the overall package size and to improve performance of the semiconductor device 200. Based on the face-to-face packaging of the dies, the semiconductor device 200 may (e.g., face-to-face dual-die-packages) may be associated with other effects such as parasitic resistance and capacitance of the edge-to-center RDL routing (e.g., from a die edge to a die center), which may reduce signal integrity and processing bandwidth (e.g., inhibit bandwidth scaling to support relatively higher processing speeds). Further, because the die 205 and the die 210 may share a same coupling point (e.g., the channel 215) a load impedance (e.g., load capacitance) that is experienced (e.g., “seen”) at the channel 215 may increase, further reducing further reduce signal integrity and bandwidth.

To mitigate the effects associated with the face-to-face package of the die 205 and the die 210, the semiconductor device 200 implement controlled inductance along the RDL 230 to the die 205 and the die 210 (e.g., along a signal path to a DQ channel), which may mitigate (e.g., compensate for) parasitic impedance associated with the RDL 230 and the increased load (e.g., two-times capacitive I/O load where the DQ pads from each die meet). For example, the semiconductor device 200 may be configured with one or more inductive coils (e.g., one or more T-coils, one or more mutually inductive coils, one or more spiral-shaped coils, as described in greater detail herein including with reference to FIG. 2B), which may counteract (e.g., by matching or equalizing) an impedance (e.g., a capacitance) associated the semiconductor device 200. The one or more inductive coils may be coupled with the transmission circuitry 220, the reception circuitry 225, and the memory arrays 255, which may improve signal quality and increase a processing bandwidth associated with the semiconductor device 200.

FIG. 2B shows an example of an inductive coil 202 that supports semiconductor die coupling with inductive coils in accordance with examples as disclosed herein. The inductive coil 202 (e.g., a T-coil, a spiral shaped conductor, an inductor, inductive windings) may include a pad 250, a pad 270, and a pad 260 for making electrical connections with various external components. The inductive coil 202 may itself be associated with multiple coils or multiple coiling directions. For example, at a point 275 along the inductive coil 202, electrical current may flow in one direction, and at a point 280 along the inductive coil 202, the electrical current may flow in the opposite direction relative to the point 275. Thus, the coiling (e.g., or windings) of the inductive coil 202 may be mutually inductive (e.g., either positively or negatively) based on including multiple coils. Although, the inductive coil 202 is illustrated as a non-limiting example, an inductive coil may include any quantity of coils (e.g., windings), any quantity of direction changes, and any quantity of interface pads.

By including one or more inductive coils 202 in the semiconductor device 200, the semiconductor device 200 may compensate for the parasitic impedance of the RDL 230 (e.g., of the edge-to-center RDL route) while simultaneously shielding an external channel from the increased load capacitance experienced at the channel 215. Accordingly, the semiconductor device 200 may include one or more inductive coils 202 at various locations in order to mitigate signal quality degradation and bandwidth reductions associated with the face-to-face packaging of the die 205 and the die 210.

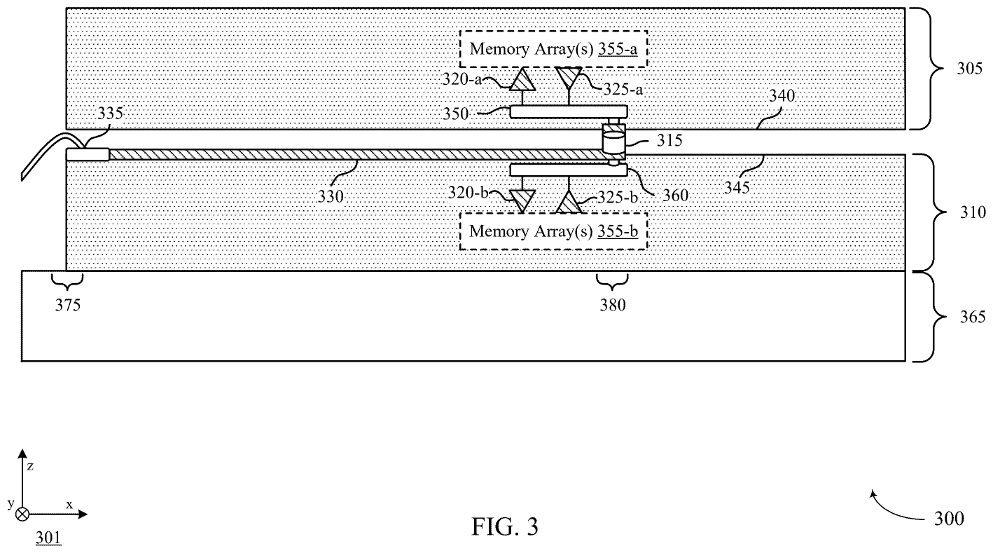

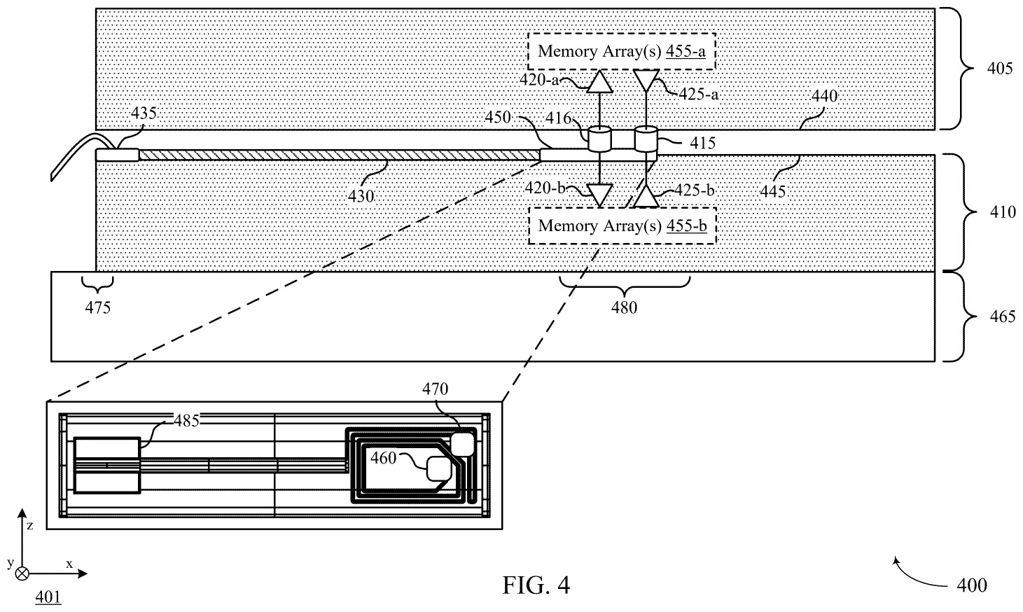

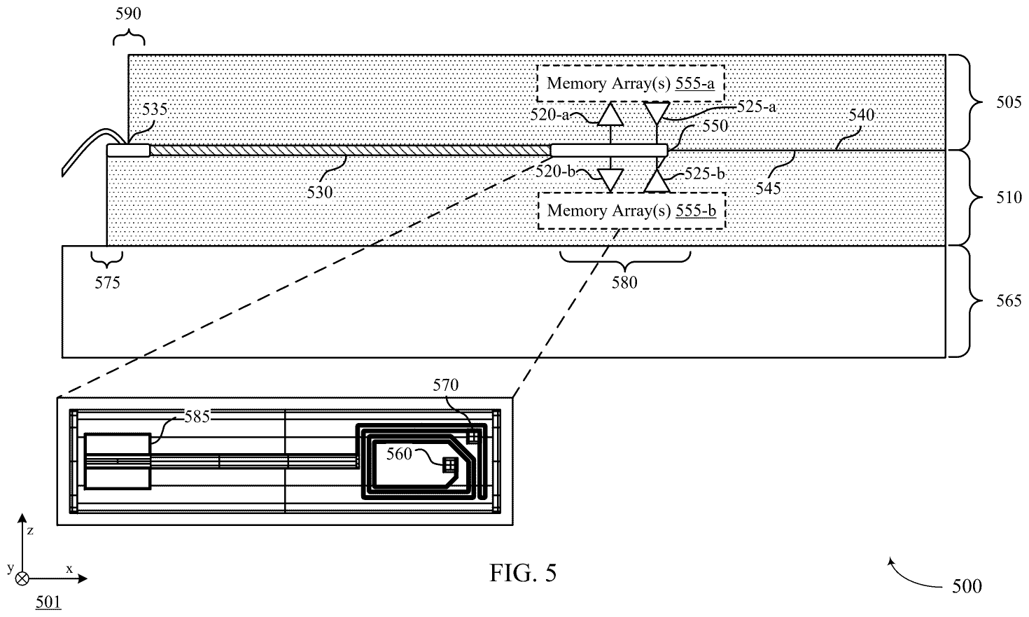

In some examples, the die 205 and the die 210 may respectively include one or more inductive coils 202 (e.g., each die may include respective T-coils) that couple the die circuitry with a channel 215, which may be described in greater detail herein, including with reference to FIG. 3. In some other examples, the RDL 230 may include one or more inductive coils 202 that are shared between the die 205 and the die 210. The die 205 and the die 210 may be coupled with the one or more inductive coils 202 based on one or more conductive pillars (e.g., a solder contact, a copper pillar), which may be described in greater detail herein, including with reference to FIG. 4. Alternatively, the die 205 and the die 210 may be coupled with the one or more inductive coils 202 based on a hybrid bonding technique, which may be described in greater detail herein, including with reference to FIG. 5. Accordingly, semiconductor devices 200 may be enabled to support improved signal integrity and improved bandwidth capability (e.g., faster processing speeds), which may further enable improved densification of semiconductor device 200.

FIG. 3 shows an example of a semiconductor device 300 that supports semiconductor die coupling with inductive coils in accordance with examples as disclosed herein. The semiconductor device 300 (e.g., a face-to-face dual-die package) may be an example of or include a system 100, a host system 105, a memory system 110, or a semiconductor device 200 as described with reference to FIGS. 1 and 2A. The semiconductor device 300 may be described with reference to an x-direction (e.g., a width direction), a y-direction (e.g., a height direction), and a z-direction (e.g., a depth direction) of the coordinate system 301. The semiconductor device 300 may include a die 305 (e.g., a top die, a memory array die, a memory device 145, a semiconductor die), a die 310 (e.g., a bottom die, a memory array die, a memory device 145, a semiconductor die), and a substrate 365 (e.g., a package substrate, positioned below the die 305 and the die 310). The die 305 and the die 310 may be coupled with an RDL 330 (e.g., which may be coupled with a wire bond 335) via a conductive pillar 315 (e.g., a channel 215, a solder ball, a copper pillar). The semiconductor device 300 may also include a substrate 365 (e.g., a substrate material, a package substrate) that is positioned below a back side of the die 310 opposite a front side 345 of the die 310. In some examples, the die 305 and the die 310 may be mechanically supported (e.g., as a package) based on the substrate 365.

The semiconductor device 300 may be a non-limiting example of the semiconductor device 200, in which each die of the semiconductor device 300 respectively includes one or more inductive coils 202. The die 305 may include one or more memory arrays 355-a and one or more inductive coils 350 (e.g., an inductive coil 202, a T-coil). The one or more inductive coils 350 may be coupled with transmission circuitry 320-a (e.g., driver circuitry), reception circuitry 325-a (e.g., including ESD circuitry, receive circuitry), one or more memory arrays 355-a (e.g., memory array circuitry), and other circuitry of the die 305. The die 305 may also include a first interface (e.g., an interface of the one or more inductive coils 350, an interface between the one or more inductive coils 350 and a conductive pillar 315) positioned on a front side 340 of the die 305. The first interface may be configured with one or more first pads (e.g., a pad 250 of the one or more inductive coils 350) for making electrical connections (e.g., with the conductive pillar 315). In some examples, a conductive pillar 315 of the semiconductor device 300 may be coupled with the one or more inductive coils 350 based on the first interface.

In some examples, the die 305 may include one or more memory arrays 355-a, which may be positioned opposite the first interface of the die 305. The one or more memory arrays 355-a may be coupled with the first interface based on the transmission circuitry 320-a, the reception circuitry 325-a, or both. In some examples, the transmission circuitry 320-a, the reception circuitry 325-a, or both may be operable to access the one or more memory arrays 355-a (e.g., receive and/or transmit memory access signaling via the conductive pillar 315, an RDL 330, and the wire bond 335).

The die 310 may be coupled with the die 305 and may include one or more memory arrays 355-b and one or more inductive coils 360 (e.g., an inductive coil 202, a T-coil). The one or more inductive coils 360 may be coupled with transmission circuitry 320-b (e.g., driver circuitry), reception circuitry 325-b (e.g., including ESD circuitry, receive circuitry), one or more memory arrays 355-b (e.g., memory array circuitry), and other circuitry of the die 310. The die 310 may also include a second interface (e.g., an interface of the one or more inductive coils 360, an interface between the one or more inductive coils 360 and a conductive pillar 315) positioned on a front side 345 of the die 310. The second interface may be configured with one or more second pads (e.g., a pad 250 of the one or more inductive coils 360) for making electrical connections (e.g., with the conductive pillar 315). In some examples, the conductive pillar 315 of the semiconductor device 300 may be coupled with the one or more inductive coils 360 based on the second interface. In some examples, the one or more first pads of the first interface may mirror the one or more second pads of the second interface (e.g., to support the face-to-face packaging).

In some examples, the die 310 may include one or more memory arrays 355-b, which may be positioned opposite the second interface of the die 310. The one or more memory arrays 355-b may be coupled with the second interface based on the transmission circuitry 320-b, the reception circuitry 325-b, or both. In some examples, the transmission circuitry 320-b, the reception circuitry 325-b, or both may be operable to access the one or more memory arrays 355-b (e.g., receive and/or transmit memory access signaling via the conductive pillar 315, an RDL 330, and the wire bond 335).

The conductive pillar 315 may be coupled with the one or more inductive coils 350 of the die 305 and the one or more inductive coils 360 of the second die. In some examples, the front side 340 of the die 305 may be coupled with the front side 345 of the die 310 based on the conductive pillar 315. In some examples, the conductive pillar 315 may include a solder material, a copper material, or some other conductive material.

The RDL 330 may be positioned on the front side 345 of the die 310. In some examples, the conductive pillar 315 may extend from the front side 340 of the die 305 to the RDL 330. In some examples, the RDL 330 may be coupled with (e.g., directly coupled with) the one or more inductive coils 360. The conductive pillar 315 may be positioned at a center 380 of the die 305 and the die 310 (e.g., a die center) along a width direction of the semiconductor device 300. The RDL 330 may extend from the center 380 of the die 305 and the die 310 to an edge 375 of the die 305 and the die 310. In some examples, the wire bond 335 (e.g., including a bond wire and a contact) may be formed in (e.g., coupled with) the RDL 330 and at the edge 375 (e.g., an edge of the die 305, the die 310, or both). The wire bond 335 may also be positioned on the front side 345 of the die 310.

Although the die 310 and the die 305 are shown, as a non-limiting example, in a face-to-face package architecture, the techniques and architectures described herein may apply for back-to-face package architecture. For example, the die 305 may alternatively include a first interface (e.g., the one or more inductive coils 350, an interface between the one or more inductive coils 350 and a conductive pillar 315) positioned on a back side of the die 305 (e.g., a side opposite the front side 340, a back surface of the top die). Additionally, or alternatively, the die 305 may include the RDL 330 in the back side of the die 305.

FIG. 4 shows an example of a semiconductor device 400 that supports semiconductor die coupling with inductive coils in accordance with examples as disclosed herein. The semiconductor device 400 (e.g., a face-to-face dual-die package) may be an example of or include a system 100, a host system 105, a memory system 110, or a semiconductor device 200 as described with reference to FIGS. 1 and 2A. The semiconductor device 400 may be described with reference to an x-direction (e.g., a width direction), a y-direction (e.g., a height direction), and a z-direction (e.g., a depth direction) of the coordinate system 401. The semiconductor device 400 may include a die 405 (e.g., a top die, a memory array die, a memory device 145, a semiconductor die), a die 410 (e.g., a bottom die, a memory array die, a memory device 145, a semiconductor die), and a substrate 465 (e.g., a package substrate, positioned below the die 405 and the die 410). The die 405 and the die 410 may be coupled with an RDL 430 (e.g., which may be coupled with a wire bond 435) via one or more conductive pillars (e.g., a conductive pillar 415 and a conductive pillar 416, a channel 215, a solder ball, a copper pillar). The semiconductor device 400 may also include a substrate 465 (e.g., a substrate material, a package substrate) that is positioned below a back side of the die 410 opposite the front side 445 of the die 410. In some examples, the die 405 and the die 410 may be mechanically supported (e.g., as a package) based on the substrate 465.

The semiconductor device 400 may be a non-limiting example of the semiconductor device 200, in which each die of the semiconductor device 400 are coupled with one or more inductive coils 450 (e.g., an inductive coil 202, a shared inductive coil, one or more inductive coils 202). Such examples may be associated with reduced die area, reduced metal resources, and improved power delivery. The die 405 may include transmission circuitry 420-a (e.g., driver circuitry), reception circuitry 425-a (e.g., including ESD circuitry, receive circuitry), one or more memory arrays 455-a (e.g., memory array circuitry), and other circuitry. In some examples, the transmission circuitry 420-a, the reception circuitry 425-a, or both may be operable to access the one or more memory arrays 455-a (e.g., receive and/or transmit memory access signaling via the conductive pillars 415 and 416, the RDL 430, and the wire bond 435). The die 405 may also include a first interface (e.g., an interface between the circuitry of the die 405 and the conductive pillars 415 and 416) positioned on a front side 440 of the die 405. The first interface may be configured with one or more first pads for making electrical connections (e.g., with the conductive pillars 415 and 416). The one or more conductive pillars (e.g., the conductive pillars 415 and 416) may be coupled with the front side 440 of the die 405 based on the first interface. The one or more memory arrays 455-a may be positioned opposite the first interface of the die 405 and may be coupled with the first interface based on the transmission circuitry 420-a, the reception circuitry 425-a, or both.

The die 410 may include transmission circuitry 420-b (e.g., driver circuitry), reception circuitry 425-b (e.g., including ESD circuitry, receive circuitry), one or more memory arrays 455-b (e.g., memory array circuitry), and other circuitry. In some examples, the transmission circuitry 420-b, the reception circuitry 425-b, or both may be operable to access the one or more memory arrays 455-b (e.g., receive and/or transmit memory access signaling via the conductive pillars 415 and 416, the RDL 430, and the wire bond 435). The die 410 may also include a second interface (e.g., an interface between the circuitry of the die 410 and the conductive pillars 415 and 416) positioned on the front side 445 of the die 410. The second interface may be configured with one or more second pads for making electrical connections (e.g., with the conductive pillars 415 and 416). The one or more inductive coils 450 may be coupled with the front side 440 of the die 405 based on the second interface. The one or more memory arrays 455-b may be positioned opposite the second interface of the die 410 and may be coupled with the second interface based on the transmission circuitry 420-b, the reception circuitry 425-b, or both. In some examples, the one or more one or more first pads of the first interface may mirror the one or more second pads of the second interface (e.g., to support the face-to-face packaging).

The one or more inductive coils 450 may be positioned in an RDL 430 (e.g., coupled with the RDL 430 based on a pad 485 of the one or more inductive coils 450) that is between the die 405 and the die 410. In some examples, a geometry of the one or more inductive coils 450 may be adjusted (e.g., a pad size may be increased) to support one or more pillar pads. For example, the one or more inductive coils 450 may include a conductive pad 460 coupled with a first conductive pillar of the one or more conductive pillars (e.g., a conductive pillar 416). The conductive pad 460 may be coupled with the transmission circuitry for both dies. For example, the transmission circuitry 420-a (e.g., a first transmitter circuit) of the die 405 and the transmission circuitry 420-b (e.g., a second transmitter circuit) of the die 410 may be coupled with the conductive pad 460. The one or more inductive coils 450 may also include a conductive pad 470 coupled with a second conductive pillar of the one or more conductive pillars (e.g., a conductive pillar 415). The conductive pad 470 may be coupled with the reception circuitry for both dies. For example, the reception circuitry 425-a (e.g., a first receiver circuit) of the die 405 and the reception circuitry 425-b (e.g., a second receiver circuit) of the die 410 may be coupled with the conductive pad 470.

In some examples, the RDL 430 may extend from an edge 475 of the die 405, the die 410, or both to a center 480 of the die 405, the die 410, or both along a width direction of the semiconductor device 400. The one or more conductive pillars (e.g., the conductive pillar 415 and the conductive pillar 416) may extend from the front side 440 of the die 405 to the one or more inductive coils 450. The front side 440 of the die 405 may be coupled with the front side 445 of the die 410 based on the one or more conductive pillars 415 and 416 and the one or more inductive coils 450. In some examples, the one or more conductive pillars may be positioned at the center 480 of the die 405 and the die 410 along the width direction of the semiconductor device 400. The conductive pillar 415 and the conductive pillar 416 may include a solder material, a copper material, or some other conductive material. In some examples, the wire bond 435 (e.g., including a bond wire and a contact) may be positioned on the front side 445 of the die 410 and at the edge 475 of the die 405, the die 410, or both. In some examples, a wire bond may be formed in (e.g., coupled with) RDL 430.

Although the die 410 and the die 405 are shown, as a non-limiting example, in a face-to-face package architecture, the techniques and architectures described herein may apply for back-to-face package architecture. For example, the 405 may alternatively include the first interface (e.g., an interface between the circuitry of the die 405 and the conductive pillars 415 and 416) positioned on a back side of the die 405 (e.g., a side that is opposite the front side 440, a back surface of the top die). In another example, the die 405 may alternatively include the one or more inductive coils 450 and the RDL 430 (e.g., the one or more inductive coils 450 formed using the RDL 430) on the back side of the die 405.

FIG. 5 shows an example of a semiconductor device 500 that supports semiconductor die coupling with inductive coils in accordance with examples as disclosed herein. The semiconductor device 500 (e.g., a face-to-face dual-die package) may be an example of or include a system 100, a host system 105, a memory system 110, or a semiconductor device 200 as described with reference to FIGS. 1 and 2A. The semiconductor device 500 may be described with reference to an x-direction (e.g., a width direction), a y-direction (e.g., a height direction), and a z-direction (e.g., a depth direction) of the coordinate system 501. The semiconductor device 500 may include a die 505 (e.g., a top die, a memory array die, a memory device 145, a semiconductor die), a die 510 (e.g., a bottom die, a memory array die, a memory device 145, a semiconductor die), and a substrate 565 (e.g., a package substrate, positioned below the die 505 and the die 510). The die 505 and the die 510 may be coupled with an RDL 530 (e.g., which may be coupled with a wire bond 535) via a hybrid bond between the dies. The semiconductor device 500 may also include a substrate 565 (e.g., a substrate material, a package substrate) that is positioned below a back side of the die 510 opposite the front side 545 of the die 510. In some examples, the die 505 and the die 510 may be mechanically supported (e.g., as a package) based on the substrate 565.

The semiconductor device 500 may be a non-limiting example of the semiconductor device 200, in which each die of the semiconductor device 500 are coupled with one or more inductive coils 550 (e.g., an inductive coil 202, a shared inductive coil, one or more inductive coils 202). Further, the die 505 and the die 510 may be coupled via a hybrid bond which may refer to a technique where interfacing contacts may be coupled by a fusion of conductive materials (e.g., electrically conductive materials) of the interfacing contacts (e.g., without solder or other intervening material between contacts). A hybrid bond may be an example of a permanent bond that combines a dielectric bond (SiOx) with embedded metal (Cu) to form interconnections. Hybrid bonding may enable smaller bonding pitches, higher memory cell density, improved signaling over conductive lines, improved power distribution, among other benefits.

The die 505 may include transmission circuitry 520-a (e.g., driver circuitry), reception circuitry 525-a (e.g., including ESD circuitry, receive circuitry), one or more memory arrays 555-a (e.g., memory array circuitry), and other circuitry. In some examples, the transmission circuitry 520-a, the reception circuitry 525-a, or both may be operable to access the one or more memory arrays 555-a (e.g., receive and/or transmit memory access signaling via the one or more inductive coils 550, the RDL 530, and the wire bond 535). The die 505 may also include a first interface positioned on the front side 540 of the die 505 (e.g., an interface between the circuitry of the die 505 and the front side 540). The first interface may be configured with one or more first pads for making electrical connections (e.g., with one or more pads of one or more inductive coils 550). For example, the one or more inductive coils 550 may include a conductive pad 560 and a conductive pad 570, which may be coupled with the first interface. The one or more memory arrays 555-a may be positioned opposite the first interface of the die 505 and may be coupled with the first interface based on the transmission circuitry 520-a, the reception circuitry 525-a, or both.

The die 510 may include transmission circuitry 520-b (e.g., driver circuitry), reception circuitry 525-b (e.g., including ESD circuitry, receive circuitry), one or more memory arrays 555-b (e.g., memory array circuitry), and other circuitry. The front side 545 of the die 410 may be bonded (e.g., via hybrid bonding) with the front side 540 of the die 505. In some examples, the transmission circuitry 520-b, the reception circuitry 525-b, or both may be operable to access the one or more memory arrays 555-b (e.g., receive and/or transmit memory access signaling via the one or more inductive coils 550, the RDL 530, and the wire bond 535). The die 510 may also include a second interface positioned on the front side 545 of the die 510 (e.g., an interface between the circuitry of the die 505 and the front side 545). The second interface may be configured with one or more second pads for making electrical connections (e.g., with the conductive pad 560 and the conductive pad 570 of one or more inductive coils 550). For example, the conductive pad 560 and the conductive pad 570 may be coupled with the second interface. The one or more memory arrays 555-b may be positioned opposite the second interface of the die 510 and may be coupled with the second interface based on the transmission circuitry 520-b, the reception circuitry 525-b, or both. In some examples, the one or more one or more first pads of the first interface may mirror the one or more second pads of the second interface (e.g., to support the face-to-face packaging).

The one or more inductive coils 550 may be positioned in an RDL 530 (e.g., coupled with the RDL 530 based on a pad 585 of the one or more inductive coils 550) on the front side 545 of the die 510. In some examples, the conductive pad 560 and the conductive pad 570 may be coupled with (e.g., directly with) the circuitry of the die 505 and the die 510. For example, the conductive pad 560 may be coupled with both of the transmission circuitry 520-a (e.g., a first transmitter circuit) of the die 505 and the transmission circuitry 520-b (e.g., a second transmitter circuit) of the die 510. The conductive pad 570 may be coupled with both of the reception circuitry 525-a (e.g., a first receiver circuit) of the die 505 and the reception circuitry 525-b (e.g., a second receiver circuit) of the die 510. In some examples, the one or more inductive coils 550 may be positioned at a center 580 of the die 510 along a width direction of the semiconductor device 500.

In some examples, the RDL 530 may extend from an edge 575 of the die 510 to a center 580 of the die 505, the die 510, or both along the width direction of the semiconductor device 500. In some examples, an edge 590 of the die 510 may be offset from the edge 575 of the second die. That is the edge 590 of the die 505 may not align with the edge 575 of the die 510 (e.g., the dies may be shingle-stacked), which may provide a location on the semiconductor device 500 to support the wire bond 535. The wire bond 535 (e.g., include a bond wire and a contact) may be positioned on the edge 575 of the die 510. wherein the wire bond contact is formed in (e.g., coupled with) the RDL 530.

Although the die 510 and the die 505 are shown, as a non-limiting example, in a face-to-face package architecture, the techniques and architectures described herein may apply for back-to-face package architecture. For example, the 505 may alternatively include the first interface (e.g., an interface between the circuitry of the die 505 and the one or more inductive coils 550) positioned on a back side of the die 505 (e.g., a side that is opposite the front side 540, a back surface of the top die). In another example, the die 505 may alternatively include the one or more inductive coils 550 and the RDL 530 (e.g., the one or more inductive coils 550 formed using the RDL 530) on the back side of the die 505.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A semiconductor device, including: a first die including one or more first inductive coils that are coupled with first circuitry of the first die; a second die coupled with the first die, the second die including one or more second inductive coils that are coupled with second circuitry of the second die; and a conductive pillar coupled with the one or more first inductive coils of the first die and the one or more second inductive coils of the second die, where a front side of the first die is coupled with a front side of the second die based at least in part on the conductive pillar.

Aspect 2: The semiconductor device of aspect 1, where the first die includes: a first interface positioned on the front side of the first die and configured with one or more first pads for making electrical connections, where the conductive pillar is coupled with the one or more first inductive coils based at least in part on the first interface; and a first memory array positioned opposite the first interface and coupled with the first interface based at least in part on the first circuitry.

Aspect 3: The semiconductor device of aspect 2, where the second die includes: a second interface positioned on the front side of the second die and configured with one or more second pads for making electrical connections, where the conductive pillar is coupled with the one or more second inductive coils based at least in part on the second interface; and a second memory array positioned opposite the second interface and coupled with the second interface based at least in part on the second circuitry.

Aspect 4: The semiconductor device of aspect 3, where the one or more first pads of the first interface mirrors the one or more second pads of the second interface.

Aspect 5: The semiconductor device of any of aspects 1 through 4, further including: a redistribution layer positioned on the front side of the second die, where the conductive pillar extends from the front side of the first die to the redistribution layer, and the redistribution layer is coupled with the one or more second inductive coils.

Aspect 6: The semiconductor device of aspect 5, where the conductive pillar is positioned at a center of the first die and the second die along a width direction of the semiconductor device, and the redistribution layer extends from the center of the first die and the second die to an edge of the first die and the second die.

Aspect 7: The semiconductor device of any of aspects 1 through 6, further including: a substrate material positioned below a back side of the second die opposite the front side, where the first die and the second die are mechanically supported based at least in part on the substrate material.

Aspect 8: The semiconductor device of any of aspects 1 through 7, where: the first circuitry includes first transmission circuitry, first reception circuitry, first electrostatic discharge circuitry, first memory array circuitry, or any combination thereof; and the second circuitry includes second transmission circuitry, second reception circuitry, second electrostatic discharge circuitry, second memory array circuitry, or any combination thereof.

Aspect 9: The semiconductor device of any of aspects 1 through 8, where the conductive pillar includes a solder material or a copper material.

Aspect 10: The semiconductor device of any of aspects 1 through 9, further including: a wire bond contact formed in a redistribution layer and at an edge of the second die.

An apparatus is described. The following provides an overview of aspects of the apparatus as described herein:

Aspect 11: A semiconductor device, including: a first die including first circuitry; a second die including second circuitry; one or more inductive coils positioned in a redistribution layer between the first die and the second die; and one or more conductive pillars extending from a front side of the first die to the one or more inductive coils, where the front side of the first die is coupled with a front side of the second die based at least in part on the one or more conductive pillars and the one or more inductive coils.

Aspect 12: The semiconductor device of aspect 11, where the first die includes: a first interface positioned on the front side of the first die and configured with one or more first pads for making electrical connections, where the one or more conductive pillars are coupled with the front side of the first die based at least in part on the first interface; and a first memory array positioned opposite the first interface and coupled with the first interface based at least in part on the first circuitry.

Aspect 13: The semiconductor device of aspect 12, where the second die includes: a second interface positioned on the front side of the second die and configured with one or more second pads for making electrical connections, where the one or more inductive coils are coupled with the front side of the second die based at least in part on the second interface; and a second memory array positioned opposite the second interface and coupled with the second interface based at least in part on the second circuitry.

Aspect 14: The semiconductor device of aspect 13, where the one or more first pads of the first interface mirrors the one or more second pads of the second interface.

Aspect 15: The semiconductor device of any of aspects 11 through 14, where the redistribution layer extends from an edge of the first die and the second die to a center of the first die and the second die along a width direction of the semiconductor device.

Aspect 16: The semiconductor device of aspect 15, where the one or more conductive pillars are positioned at the center of the first die and the second die along the width direction of the semiconductor device.

Aspect 17: The semiconductor device of any of aspects 11 through 16, further including: a substrate material positioned below a back side of the second die opposite the front side, where the first die and the second die are mechanically supported based at least in part on the substrate material.

Aspect 18: The semiconductor device of any of aspects 11 through 17, where the first circuitry and the second circuitry include respective transmitter circuitry, respective receiver circuitry, respective electrostatic discharge circuitry, respective memory array circuitry, or any combination thereof.

Aspect 19: The semiconductor device of aspect 18, where: the first circuitry includes a first transmitter circuit and a first receiver circuit and the second circuitry includes a second transmitter circuit and a second receiver circuit; the first transmitter circuit and the second transmitter circuit are coupled with a first conductive pillar of the one or more conductive pillars; and the first receiver circuit and the second receiver circuit are coupled with a second conductive pillar of the one or more conductive pillars.

Aspect 20: The semiconductor device of any of aspects 11 through 19, where the one or more conductive pillars include a solder material or a copper material.

Aspect 21: The semiconductor device of any of aspects 11 through 20, where the one or more inductive coils include: a first conductive pad coupled with a first conductive pillar of the one or more conductive pillars, where the first conductive pad is coupled with a first transmitter circuit of the first circuitry and a second transmitter circuit of the second circuitry; and a second conductive pad coupled with a second conductive pillar of the one or more conductive pillars, where the second conductive pad is coupled with a first receiver circuit of the first circuitry and a second receiver circuit of the second circuitry.

Aspect 22: The semiconductor device of any of aspects 11 through 21, further including: a wire bond contact positioned on the front side of the second die and at an edge of the second die, where the wire bond contact is formed in the redistribution layer.

An apparatus is described. The following provides an overview of aspects of the apparatus as described herein:

Aspect 23: A semiconductor device, including: a first die including first circuitry; a second die including second circuitry, where a front side of the second die is bonded with a front side of the first die; and one or more inductive coils positioned in a redistribution layer on the front side of the second die, where the one or more inductive coils include one or more conductive pads that are coupled with the first circuitry of the first die and the second circuitry of the second die.

Aspect 24: The semiconductor device of aspect 23, where the first die includes: a first interface positioned on the front side of the first die and configured with one or more first pads for making electrical connections, where the one or more conductive pads of the one or more inductive coils are coupled with the first interface; and a first memory array positioned opposite the first interface and coupled with the first interface based at least in part on the first circuitry.

Aspect 25: The semiconductor device of aspect 24, where the second die includes: a second interface positioned on the front side of the second die and configured with one or more second pads for making electrical connections, where the one or more conductive pads of the one or more inductive coils are coupled with the second interface; and a second memory array positioned opposite the second interface and coupled with the second interface based at least in part on the second circuitry.

Aspect 26: The semiconductor device of aspect 25, where the one or more first pads of the first interface mirrors the one or more second pads of the second interface.

Aspect 27: The semiconductor device of any of aspects 23 through 26, where the redistribution layer extends from an edge of the second die to a center of the second die along a width direction of the semiconductor device.

Aspect 28: The semiconductor device of aspect 27, where the one or more inductive coils are positioned at the center of the second die along the width direction of the semiconductor device.

Aspect 29: The semiconductor device of any of aspects 23 through 28, further including: a substrate material positioned below a back side of the second die opposite the front side, where the first die and the second die are mechanically supported based at least in part on the substrate material.

Aspect 30: The semiconductor device of any of aspects 23 through 29, where the first circuitry and the second circuitry include respective transmitter circuitry, respective receiver circuitry, respective electrostatic discharge circuitry, respective memory array circuitry, or any combination thereof.

Aspect 31: The semiconductor device of aspect 30, where: the first circuitry includes a first transmitter circuit and a first receiver circuit and the second circuitry includes a second transmitter circuit and a second receiver circuit; the first transmitter circuit and the second transmitter circuit are coupled with a first conductive pads of the one or more conductive pads; and the first receiver circuit and the second receiver circuit are coupled with a second conductive pads of the one or more conductive pads.

Aspect 32: The semiconductor device of any of aspects 23 through 31, where the one or more inductive coils include: a first conductive pad coupled with both a first transmitter circuit of the first circuitry and a second transmitter circuit of the second circuitry; and a second conductive pad coupled with both a first receiver circuit of the first circuitry and a second receiver circuit of the second circuitry.

Aspect 33: The semiconductor device of any of aspects 23 through 32, where an edge of the first die is offset from an edge of the second die, the semiconductor device further including: a wire bond contact positioned on the edge of the second die, where the wire bond contact is formed in the redistribution layer.

An apparatus is described. The following provides an overview of aspects of the apparatus as described herein:

Aspect 34: A memory system, including: a first die including one or more first memory arrays and one or more first inductive coils that are coupled with first circuitry of the first die, the first circuitry operable to access the one or more first memory arrays; a second die coupled with the first die, the second die including one or more second memory arrays and one or more second inductive coils that are coupled with second circuitry of the second die, the second circuitry operable to access the one or more second memory arrays; and a conductive pillar coupled with the one or more first inductive coils of the first die and the one or more second inductive coils of the second die, where a front side of the first die is coupled with a front side of the second die based at least in part on the conductive pillar.

An apparatus is described. The following provides an overview of aspects of the apparatus as described herein:

Aspect 35: A memory system, including: a first die including one or more first memory arrays and first circuitry operable to access the one or more first memory arrays; a second die including one or more second memory arrays and second circuitry operable to access the one or more second memory arrays; one or more inductive coils positioned in a redistribution layer between the first die and the second die; and one or more conductive pillars extending from a front side of the first die to the one or more inductive coils, where the front side of the first die is coupled with a front side of the second die based at least in part on the one or more conductive pillars and the one or more inductive coils.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a first die comprising one or more first inductive coils that are coupled with first circuitry of the first die;
a second die coupled with the first die, the second die comprising one or more second inductive coils that are coupled with second circuitry of the second die; and
a conductive pillar coupled with the one or more first inductive coils of the first die and the one or more second inductive coils of the second die, wherein a front side of the first die is coupled with a front side of the second die based at least in part on the conductive pillar.

2. The semiconductor device of claim 1, wherein the first die comprises:
a first interface positioned on the front side of the first die and configured with one or more first pads for making electrical connections, wherein the conductive pillar is coupled with the one or more first inductive coils based at least in part on the first interface; and
a first memory array positioned opposite the first interface and coupled with the first interface based at least in part on the first circuitry.

3. The semiconductor device of claim 2, wherein the second die comprises:
a second interface positioned on the front side of the second die and configured with one or more second pads for making electrical connections, wherein the conductive pillar is coupled with the one or more second inductive coils based at least in part on the second interface; and
a second memory array positioned opposite the second interface and coupled with the second interface based at least in part on the second circuitry.

4. The semiconductor device of claim 3, wherein the one or more first pads of the first interface mirrors the one or more second pads of the second interface.

5. The semiconductor device of claim 1, further comprising:
a redistribution layer positioned on the front side of the second die, wherein:
the conductive pillar extends from the front side of the first die to the redistribution layer,
the redistribution layer is coupled with the one or more second inductive coils,
the conductive pillar is positioned at a center of the first die and the second die along a width direction of the semiconductor device, and
the redistribution layer extends from the center of the first die and the second die to an edge of the first die and the second die.

6. The semiconductor device of claim 1, further comprising:
a substrate material positioned below a back side of the second die opposite the front side, wherein the first die and the second die are mechanically supported based at least in part on the substrate material.

7. The semiconductor device of claim 1, wherein:
the first circuitry comprises first transmission circuitry, first reception circuitry, first electrostatic discharge circuitry, first memory array circuitry, or any combination thereof; and
the second circuitry comprises second transmission circuitry, second reception circuitry, second electrostatic discharge circuitry, second memory array circuitry, or any combination thereof.

8. The semiconductor device of claim 1, wherein the conductive pillar comprises a solder material or a copper material.

9. The semiconductor device of claim 1, further comprising:
a wire bond contact formed in a redistribution layer and at an edge of the second die.

10. A semiconductor device, comprising:
a first die comprising first circuitry;
a second die comprising second circuitry;
one or more inductive coils positioned in a redistribution layer between the first die and the second die; and
one or more conductive pillars extending from a front side of the first die to the one or more inductive coils, wherein the front side of the first die is coupled with a front side of the second die based at least in part on the one or more conductive pillars and the one or more inductive coils.

11. The semiconductor device of claim 10, wherein the first die comprises:
a first interface positioned on the front side of the first die and configured with one or more first pads for making electrical connections, wherein the one or more conductive pillars are coupled with the front side of the first die based at least in part on the first interface; and
a first memory array positioned opposite the first interface and coupled with the first interface based at least in part on the first circuitry.

12. The semiconductor device of claim 11, wherein the second die comprises:
a second interface positioned on the front side of the second die and configured with one or more second pads for making electrical connections, wherein the one or more inductive coils are coupled with the front side of the second die based at least in part on the second interface, and wherein the one or more first pads of the first interface mirrors the one or more second pads of the second interface; and
a second memory array positioned opposite the second interface and coupled with the second interface based at least in part on the second circuitry.

13. The semiconductor device of claim 10, wherein the redistribution layer extends from an edge of the first die and the second die to a center of the first die and the second die along a width direction of the semiconductor device, and wherein the one or more conductive pillars are positioned at the center of the first die and the second die along the width direction of the semiconductor device.

14. The semiconductor device of claim 10, further comprising:
a substrate material positioned below a back side of the second die opposite the front side, wherein the first die and the second die are mechanically supported based at least in part on the substrate material.

15. The semiconductor device of claim 10, wherein the first circuitry and the second circuitry comprise respective transmitter circuitry, respective receiver circuitry, respective electrostatic discharge circuitry, respective memory array circuitry, or any combination thereof.

16. The semiconductor device of claim 15, wherein:
the first circuitry comprises a first transmitter circuit and a first receiver circuit and the second circuitry comprises a second transmitter circuit and a second receiver circuit;
the first transmitter circuit and the second transmitter circuit are coupled with a first conductive pillar of the one or more conductive pillars; and
the first receiver circuit and the second receiver circuit are coupled with a second conductive pillar of the one or more conductive pillars.

17. The semiconductor device of claim 10, wherein the one or more inductive coils comprise:
a first conductive pad coupled with a first conductive pillar of the one or more conductive pillars, wherein the first conductive pad is coupled with a first transmitter circuit of the first circuitry and a second transmitter circuit of the second circuitry; and
a second conductive pad coupled with a second conductive pillar of the one or more conductive pillars, wherein the second conductive pad is coupled with a first receiver circuit of the first circuitry and a second receiver circuit of the second circuitry.

18. The semiconductor device of claim 10, further comprising:
a wire bond contact positioned on the front side of the second die and at an edge of the second die, wherein the wire bond contact is formed in the redistribution layer.

19. A semiconductor device, comprising:
a first die comprising first circuitry;
a second die comprising second circuitry, wherein a front side of the second die is bonded with a front side of the first die; and
one or more inductive coils positioned in a redistribution layer on the front side of the second die, wherein the one or more inductive coils comprise one or more conductive pads that are coupled with the first circuitry of the first die and the second circuitry of the second die.

20. The semiconductor device of claim 19, wherein the first die comprises:
a first interface positioned on the front side of the first die and configured with one or more first pads for making electrical connections, wherein the one or more conductive pads of the one or more inductive coils are coupled with the first interface; and
a first memory array positioned opposite the first interface and coupled with the first interface based at least in part on the first circuitry.

21. The semiconductor device of claim 20, wherein the second die comprises:
a second interface positioned on the front side of the second die and configured with one or more second pads for making electrical connections, wherein the one or more conductive pads of the one or more inductive coils are coupled with the second interface, and wherein the one or more first pads of the first interface mirrors the one or more second pads of the second interface; and
a second memory array positioned opposite the second interface and coupled with the second interface based at least in part on the second circuitry.

22. The semiconductor device of claim 19, wherein the redistribution layer extends from an edge of the second die to a center of the second die along a width direction of the semiconductor device, and wherein the one or more inductive coils are positioned at the center of the second die along the width direction of the semiconductor device.

23. The semiconductor device of claim 19, further comprising:
a substrate material positioned below a back side of the second die opposite the front side, wherein the first die and the second die are mechanically supported based at least in part on the substrate material.

24. The semiconductor device of claim 19, wherein:
the first circuitry comprises a first transmitter circuit and a first receiver circuit and the second circuitry comprises a second transmitter circuit and a second receiver circuit;
the first transmitter circuit and the second transmitter circuit are coupled with a first conductive pads of the one or more conductive pads; and
the first receiver circuit and the second receiver circuit are coupled with a second conductive pads of the one or more conductive pads.

25. The semiconductor device of claim 19, wherein the one or more inductive coils comprise:
a first conductive pad coupled with both a first transmitter circuit of the first circuitry and a second transmitter circuit of the second circuitry; and
a second conductive pad coupled with both a first receiver circuit of the first circuitry and a second receiver circuit of the second circuitry.

26. The semiconductor device of claim 19, wherein an edge of the first die is offset from an edge of the second die, the semiconductor device further comprising:
a wire bond contact positioned on the edge of the second die, wherein the wire bond contact is formed in the redistribution layer.

27. A memory system, comprising:
a first die comprising one or more first memory arrays and one or more first inductive coils that are coupled with first circuitry of the first die, the first circuitry operable to access the one or more first memory arrays;
a second die coupled with the first die, the second die comprising one or more second memory arrays and one or more second inductive coils that are coupled with second circuitry of the second die, the second circuitry operable to access the one or more second memory arrays; and
a conductive pillar coupled with the one or more first inductive coils of the first die and the one or more second inductive coils of the second die, wherein a front side of the first die is coupled with a front side of the second die based at least in part on the conductive pillar.

28. A memory system, comprising:
a first die comprising one or more first memory arrays and first circuitry operable to access the one or more first memory arrays;
a second die comprising one or more second memory arrays and second circuitry operable to access the one or more second memory arrays;
one or more inductive coils positioned in a redistribution layer between the first die and the second die; and
one or more conductive pillars extending from a front side of the first die to the one or more inductive coils, wherein the front side of the first die is coupled with a front side of the second die based at least in part on the one or more conductive pillars and the one or more inductive coils.
